(19) United States
(12) Patent Application Publication
(10) Pub. No.: US 2024/0289413 A1
(43) Pub. Date: Aug. 29, 2024

(54) METHOD AND APPARATUS FOR IDENTIFYING PARAMETER OF BATTERY MODEL, AND ELECTRONIC DEVICE

(71) Applicant: Shanghai Makesens Energy Storage Technology Co., Ltd., Shanghai (CN)

(72) Inventors: Xiaohua Chen, Shanghai (CN); Zhimin Zhou, Shanghai (CN); Qiong Wei, Shanghai (CN); Xiao Yan, Shanghai (CN); Enhai Zhao, Shanghai (CN); Pingchao Hao, Shanghai (CN); Zhou Yang, Shanghai (CN)

(73) Assignee: Shanghai Makesens Energy Storage Technology Co., Ltd., Shanghai (CN)

(21) Appl. No.: 18/503,206

(22) Filed: Nov. 7, 2023

(30) Foreign Application Priority Data
Feb. 27, 2023 (CN) 202310177245.0

(51) Int. Cl. G01R 31/367; G01R 31/396

(52) U.S. Cl. CPC G06F 17/11; G01R 31/367; G01R 31/396; G06F 17/18

(57) ABSTRACT

Provided are a method and an apparatus for identifying a parameter of a battery model, an electronic device, and a storage medium. The method includes: obtaining to-be-identified parameters from an electrochemical model to form individuals; calculating a first fitness for each individual; determining a cell parameter if any individual has a first fitness less than a fitness threshold; sorting the individuals in an ascending order based on magnitudes of the first fitness, and partition the individuals into two parts in a case that each individual has a first fitness greater than or equal to the fitness threshold; updating to sub-individuals obtained from partition; calculating a second fitness for each individual, compare the second fitness with the first fitness, and retain an individual having a smaller fitness; and terminates if a fitness of the retained individual is less than the fitness threshold.

### CROSS-REFERENCE TO RELATED APPLICATION

This application claims priority to Chinese Patent Application No. 202310177245.0, filed on Feb. 27, 2023, which is incorporated herein by its reference in its entirety.

### FIELD

The present disclosure relates to the technical field of lithium batteries, and particularly to a method and apparatus for identifying a parameter of a battery model, and an electronic device.

### BACKGROUND

A lithium battery is an important component of an energy storage power station. In order to ensure a safe operation of the lithium battery, it is necessary to identify an internal parameter of the lithium battery to facilitate accurate monitoring of changes within the lithium battery. A pseudo-two-dimension electrochemical model of a lithium-ion battery includes all basic components of a lithium battery and may be used for monitoring and identifying an internal parameter of the lithium battery. However, the related electrochemical model is complex in form, which is not conducive to optimization, and results in difficulty in identifying a high-dimensional parameter of the electrochemical model.

### SUMMARY

To solve the technical problems exists in the conventional technology, a method and apparatus for identifying a parameter of a battery model, and an electronic device are provided in embodiments of the present disclosure.

In a first aspect, a method for identifying a parameter of a battery model is provided according to an embodiment of the present disclosure. The method is applied to an energy storage power station. The method includes: establishing an electrochemical model of a cell in the energy storage power station, obtaining required to-be-identified parameters from the electrochemical model to form an individual, where the individual is a collection of all the to-be-identified parameters, and a quantity of the individual is more than one; performing multiple iterations on values of the to-be identified parameters in the individual, determining an optimal parameter from the individual, initializing all individuals, and calculating, for each of the individuals, a first fitness of the individual; determining a to-be-identified parameter from an individual having a smallest first fitness among all the individuals as a global optimal parameter; determining the global optimal parameter as parameter data of the cell, in a case that any of the individuals has a first fitness less than a fitness threshold; sorting the individuals in an ascending order based on magnitudes of the first fitness, and determining a partitioning coefficient and partitioning the individuals into two parts by using the partitioning coefficient to obtain a first population and a second population, in a case that each of the individuals has a first fitness greater than or equal to the fitness threshold; updating, by using a particle swarm algorithm, values of the to-be-identified parameters in each individual in the second population, and updating, by using a Levy flight algorithm, values of the to-be-identified parameters in each individual in the first population; merging the first population and the second population, after the to-be-identified parameters are updated, to obtain individuals having updated to-be-identified parameters, and calculating a second fitness of each of the individuals having updated to-be-identified parameters, comparing the second fitness of each individual with the first fitness of the individual, and retaining the individual having a smaller fitness value; and determining a parameter value of an individual having the updated to-be-identified parameters which corresponds to a smallest second fitness as a global optimal parameter of the updated to-be-identified parameters, in a case that the smallest second fitness is less than the fitness threshold, and determining the global optimal parameter of the updated to-be-identified parameters as parameter data of the cell.

In a second aspect, an apparatus for identifying a parameter of a battery model is provided according to an embodiment of the present disclosure. The apparatus includes: a modeling module, configured to establish an electrochemical model of a cell in the energy storage power station, obtain required to-be-identified parameters from the electrochemical model to form an individual, where the individual is a collection of all the to-be-identified parameters; an initialization module, configured to perform multiple iterations on values of the to-be identified parameters in the individual, determine an optimal parameter from the individual and obtain multiple individuals, initialize all individuals, and calculate, for each of the individuals, a first fitness of the individual; and determine a to-be-identified parameter from an individual having a smallest first fitness among all the individuals as a global optimal parameter; a detect module, configured to determine the global optimal parameter as parameter data of the cell, in a case that any of the individuals has a first fitness less than a fitness threshold; a partition module, configured to sort the individuals in an ascending order based on magnitudes of the first fitness, and determine a partitioning coefficient and partition the individuals into two parts by using the partitioning coefficient to obtain a first population and a second population, in a case that each of the individuals has a first fitness greater than or equal to the fitness threshold; an update module, configured to update, by using a particle swarm algorithm, values of the to-be-identified parameters in each individual in the second population, and update, by using a Levy flight algorithm, values of the to-be-identified parameters in each individual in the first population; a merge module, configured to merge the first population and the second population, after the to-be-identified parameters are updated, to obtain individuals having updated to-be-identified parameters, and calculate a second fitness of each of the individuals having updated to-be-identified parameters, compare the second fitness of each individual with the first fitness of the individual, and retain the individual having a smaller fitness value; and a determination module, configured to determine a parameter value of an individual having the updated to-be-identified parameters which corresponds to a smallest second fitness as a global optimal parameter of the updated to-be-identified parameters, in a case that the smallest second fitness is less than the fitness threshold, and determining the global optimal parameter of the updated to-be-identified parameters as parameter data of the cell.

In a third aspect, an electronic device is provided according to an embodiment of the present disclosure. The electronic device includes a bus, a transceiver, a memory, a processor, and a computer program stored on the memory and executable on the processor. The transceiver, the memory, and the processor are connected to each other via the bus. The computer program, when executed by the processor, performs the method according to the first aspect.

In a fourth aspect, a computer-readable storage medium storing a computer program is provided according to an embodiment of the present disclosure. The computer program, when executed by the processor, performs the method according to the first aspect.

In the solution provided in the first to fourth aspects of the present disclosure, the required to-be-identified parameters are obtained by establishing the electrochemical model of the core. All the to-be-identified parameters are formed into an individual. An optimal parameter of the individual is determined through multiple iterations. Each individual is initialized and a first fitness is calculated. An individual having the smallest first fitness among all individuals is determined as a global optimal parameter. In a case that the first fitness of at least one of the individuals is less than the fitness threshold, the global optimal parameter is determined as parameter data of the cell. In a case that the first fitness of each individual is greater than or equal to the fitness threshold, then the process proceeds to sorting all the individuals in an ascending order based on magnitudes of the first fitness and partition the individuals into two parts, i.e., the first population and the second population. The first fitness of the first population is smaller than that of the second population, or in other words, the first fitness of the second population is relatively great. The to-be-identified parameters in the first population are updated by using the Levy flight algorithm. The to-be-identified parameters in the second population are updated by using the particle swarm algorithm. After the update, the two populations are merged into one and the second fitness is calculated and compared with the first fitness. An individual having a smaller fitness is retained. The process terminates in a case that the second fitness is less than the fitness threshold. Otherwise, the individuals are partitioned again, until the re-calculated second fitness is less than the fitness threshold. Compared with the conventional technology which requires multiple manual measurements of a cell-related parameters, the parameter data that needs to be identified for the cell can be automatically obtained through the method in the present disclosure, without manual acquisition for the multiple parameters in the cell. Hence, a labor intensity and labor cost can be effectively reduced. In addition, with the randomness and global optimization characteristics of the particle swarm algorithm and the fast optimization characteristics of the Levy flight algorithm, an excellence of parameter identification for a cell in a high-dimensional space is further improved, and an accuracy of the parameter identification for the cell is improved.

### BRIEF DESCRIPTION OF THE DRAWINGS

In order clearer illustration of the technical solutions in the embodiments of the present disclosure or the background technology, accompanying drawings required to be used in the embodiments or the background technology of the present disclosure are described below.

FIG. 1 shows a flowchart 1 of a method for identifying a parameter of a battery model according to an embodiment of the present disclosure;

FIG. 2 shows a flowchart 2 of a method for identifying a parameter of a battery model according to an embodiment of the present disclosure;

FIG. 3 shows a schematic graph of variations of a with iterations in a method for identifying a parameter of a battery model according to an embodiment of the present disclosure;

FIG. 4 shows a schematic diagram of merging of a first population and a second population after to-be-identified parameters in the populations are updated through two algorithms respectively in a method for identifying a parameter of a battery model according to an embodiment of the present disclosure;

FIG. 5 shows a schematic diagram of connection of modules in an apparatus for identifying a parameter of a battery model according to an embodiment of the present disclosure; and

FIG. 6 shows a schematic structural diagram of an electronic device for identifying a parameter of a battery model according to an embodiment of the present disclosure.

### DETAILED DESCRIPTION

Hereinafter technical solutions of embodiments of the present disclosure are described clearly and completely in conjunction with the drawings of the embodiments of the present disclosure. Apparently, the embodiments described below are only some embodiments, rather than all the embodiments of the present disclosure. Any other embodiments obtained by those skilled in the art based on the embodiments in the present disclosure without any creative effort shall fall within the protection scope of the present disclosure. In order to enable those skilled in the art to better understand the solution in the present disclosure, the present disclosure is described in further detail below in conjunction with the accompanying drawings and specific embodiments.

In recent years, continuous reduction of recoverable amount of fossil fuels and environmental issues attracts more attention. New energy source (including but not limited to wind energy and solar energy) develops rapidly. Due to time dependence of the new energy source, a generated power has to be used immediately, or otherwise the power is wasted. Therefore, an energy storage system is introduced into a power system. The energy storage system can collect electric energy generated by the new energy source and output the electric energy at a stable voltage when needed. An energy storage power station in which ultra-large battery packs are used for power storage is an important supporting device and is developed and updated rapidly in recent years. In particular, a lithium-ion battery has significant advantages such as high stability, long service life, large capacity, and green environmental protection, and therefore becomes a mainstream battery technology for the energy storage power station at present.

However, due to problems of material and actual structure, the lithium-ion battery is prone to problems such as over-discharge, overcharge, overheating and degradation in practice, which results in reduced performance or failure of the lithium-ion battery. In order to ensure a safe operation and effective energy management of the energy storage power station, it is necessary to identify an internal parameter of the lithium-ion battery, and thereby effectively and accurately monitor physical and chemical changes inside the lithium-ion battery. A pseudo-two-dimensional model (P2D) of a lithium-ion battery is a common electrochemical model in scientific research and practical engineering. The model can effectively reflect physical and chemical changes inside the lithium-ion battery during use.

The electrochemical model consists of a set of partial differential equations with numerous parameters. An advantage is that the model can clearly describe an internal working mechanism of the lithium-ion battery and associate an internal state of the battery with an external behavior. With the parameters obtained, the electrochemical model can accurately simulate the internal state of the battery. However, the electrochemical models has a complex form and it is difficult to obtain the parameters through a conventional optimization process. In addition, high-dimensional parameters of the electrochemical model make it difficult to converge in identification. The present disclosure proposes a method for rapid identification of battery parameters based on P2D and in conjunction with a Levy flight algorithm and a particle swarm algorithm, in order to improve a speed and accuracy of identification.

### Embodiment 1

In this embodiment, a method for identifying a parameter of a battery model is performed by a server.

The server is connected to the energy storage power station and can collect an actual voltage of a cell through the energy storage power station.

The energy storage power station feeds back the collected actual voltage of the cell to the server.

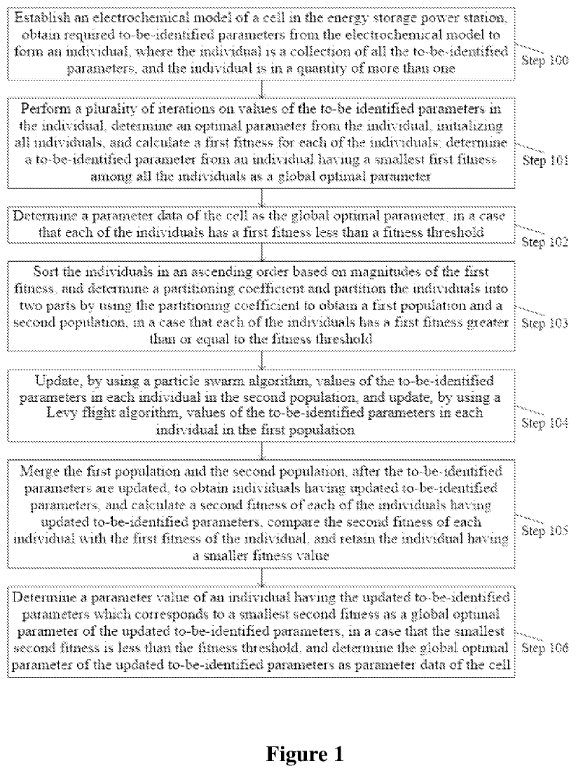

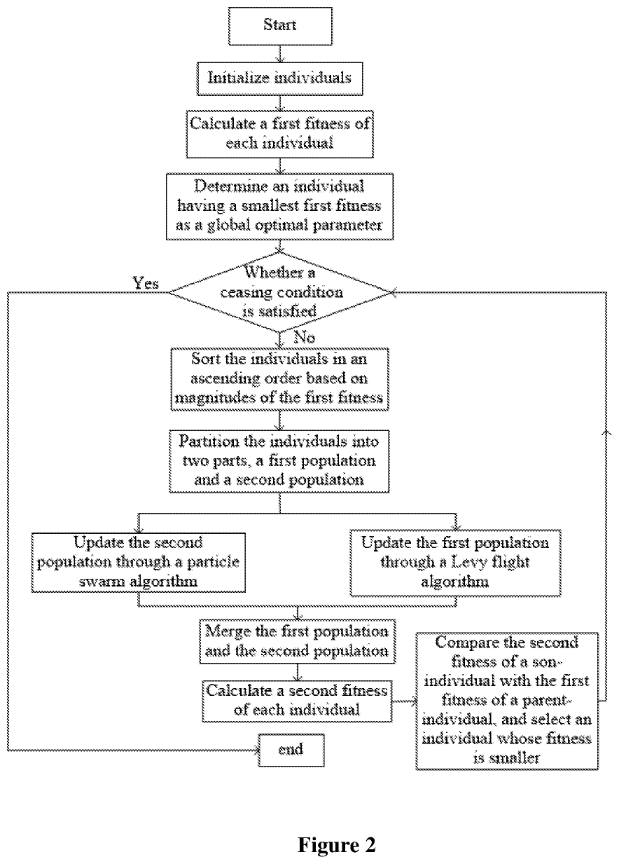

Reference is made to FIG. 1, which is a flowchart 1 of a method for identifying a parameter of a battery model according to an embodiment, and FIG. 2, which is a flowchart 2 of a method for identifying a parameter of a battery model according to an embodiment. The method provide in the embodiments is applied to the energy storage power station. The method includes steps 100 to 106 as follows.

In step 100, an electrochemical model of a cell in an energy storage power station is established, and required to-be-identified parameters are obtained from the electrochemical model to form an individual. The individual is a collection of all the to-be-identified parameters, and a quantity of the individual is more than one.

In step 100, the electrochemical model is a pseudo-two-dimensional model of a lithium-ion battery (also known as a quasi-two-dimensional model of a battery), which is a common electrochemical model. The electrochemical model can effectively reflect physical and chemical changes inside a cell during use. The to-be-identified parameters obtained from the electrochemical model are not fixed, and may be selected as needed.

In an implementation, the to-be-identified parameters obtained from the electrochemical model include, but are not limited to, an electrode parameter, a separator parameter, an electrolyte parameter, a voltage parameter, a current collector parameter and a battery dimension parameter.

After obtaining the to-be-identified parameters, the server may obtain a value range of the to-be-identified parameters.

The value range of the to-be-identified parameters is pre-cached in the server.

In particular, the electrochemical model is common in the field. Therefore, establishment of the electrochemical model of the cell in the energy storage power station (for example, the electrochemical model is a P2D, pseudo-two-dimension, model) is conventional and is not repeated here.

In step 101, multiple iterations are performed on values of the to-be identified parameters in the individual; an optimal parameter is determined from the individual; all individuals are initialized; a first fitness is calculated for each of the individuals; and a to-be-identified parameter from an individual having a smallest first fitness among all the individuals is determined as a global optimal parameter.

In step 101, the number of iterations is the same as the quantity of individuals, which are pre-set in the server. Each iteration adds a new individual. The value range of the to-be-identified parameters is preset. In each iteration, the to-be-identified parameters assume values randomly within the preset range, so that a new individual is obtained.

For example, there are five to-be-identified parameters, i.e., A, B, C, D, and E. An individual 1 obtained in step 100 may be: (A1, B1, C1, D1, E1). After an iteration on the values of the to-be-identified parameters in the individual 1, an individual 2 (a new individual): (A2, B2, C2, D2, E2) may be obtained. The same applies to the following iteration. After n iterations on the values of the to-be-identified parameters in the individual 1, an individual n (a new individual): (An, Bn, Cn, Dn, En) may be obtained.
Here, A1, A2, . . . , An are values within a value range of a to-be-identified parameter A.
B1, B2, . . . , Bn are values within a value range of a to-be-identified parameter B.
C1, C2, . . . , Cn are values within a value range of a to-be-identified parameter C.
D1, D2, . . . , Dn are values within a value range of a to-be-identified parameter D.
E1, E2, . . . , En are values within a value range of a to-be-identified parameter E.

By calculating multiple to-be-identified parameters, the first fitness corresponding to each individual can be obtained. In an implementation, the following steps (1) to (2) may be performed.

In (1), values of the to-be-identified parameters of each individual and condition data are inputted into the electrochemical model to obtain a simulated voltage of the individual.

In this step (1), the condition data refers to charge and discharge data of the cell within a certain period of time.

The server may obtain the condition data through a battery management system (BMS) connected to the server.

The battery management system is a conventional technology and is installed commonly in energy storage power stations. Therefore, principle of obtaining the condition data from the battery system is not explained here.

The server inputs the values of the to-be-identified parameters of each individual into the electrochemical model, so as to obtain a simulated voltage of the individual.

In (2), a first fitness of each individual is determined by using the simulated voltage of the individual. The first fitness satisfies:

$${MSE}_{1} = \frac{1}{m} {\sum }_{i = 1}^{m} {( {\hat{V}}_{i} - {\vec{V}}_{i} )}^{2} ;$$

where MSE₁ represents the first fitness of an individual, \hat{V}ᵢ represents a simulated voltage recorded in a correspondence relationship between an i-th simulated voltage and an actual voltage in a correspondence relationship between m simulated voltages and actual voltages, \vec{V}ᵢ represents an actual voltage recorded in correspondence relationship between an i-th simulated voltage and an actual voltage in a correspondence relationship between m simulated voltages and actual voltages, and m represents a quantity of correspondence relationship between a simulated voltage and an actual voltage.

In step (1), simulated voltages of different individuals may be obtained by determining the to-be-identified parameters in the individuals, and bring values of the to-be-identified parameters into the electrochemical model.

It should be noted that the electrochemical model is a complex equation includes multiple electrical parameters and chemical parameters, which is well-known in the art. Therefore, a process of obtaining the simulated voltage of an individual is a conventional technology and is not described here. The simulated voltage is obtained by the server through step (1). The actual voltage of the cell is collected by the energy storage power station and then transmitted from the energy storage power station to the server.

In step 102, the global optimal parameter is determined as parameter data of the cell, in a case that any of the individuals has a first fitness less than a fitness threshold.

In step 102, the first fitness threshold value of each individual is cached in the server.

This step is for determination. With the first fitness of each individual obtained through step 101, the first fitness of each individual is compared with a preset fitness threshold.

As shown in FIG. 2, in a case that any of the individuals has a first fitness less than the fitness threshold, the method according to this embodiment terminates and the global optimal parameter is determined as parameter data of the cell.

In a case that any of the individuals has a first fitness greater than or equal to the fitness threshold, it is determined that the global optimal parameter is not the parameter data required for the cell, and the method proceeds to step 103. Each cycle of an individual generates different values of the to-be-identified parameters in the individual. In a case that the values of the to-be-identified parameters are iterated multiple times and cannot be less than the fitness threshold after reaching the maximum number of iterations, the method terminates. The maximum number of iterations is set in advance as needed.

It should be noted that the fitness threshold may be modified or reset at any time based on different needs. The fitness threshold should not be understood as being unchanged once set.

In step 103, the individuals are sorted in an ascending order based on magnitudes of the first fitness, a partitioning coefficient is determined and the individuals are partitioned into two parts by using the partitioning coefficient to obtain a first population and a second population, in a case that each of the individuals has a first fitness greater than or equal to the fitness threshold. Each of the first population and the second population includes at least one to-be-identified parameter.

In an implementation of step 103, the partitioning coefficient at a current moment satisfies:

$$α = {α}_{0} + \frac{{α}_{range}}{1 + exp ( 0.01 ( t - T / 2 ) )} ;$$

where a represents a current partitioning coefficient, do represents a final partitioning coefficient, T represents a maximum number of iterations, t represents current iteration, and α₀+α_{range} represents a start partitioning coefficient. In the formula a involved in step 103, t represents the number of iterations at a current moment. The iteration needs to start from 0. Therefore, 0 is brought into the formula, and the function calculated from exp is close to 0. Then, the equation becomes

$$α = {α}_{0} + \frac{{α}_{range}}{1} ,$$

and is further simplified to α₀+α_{range}.

Here, α₀, α_{range}, t and T are known.

Values of α may be within a range from α₀+α_{range} to do, and is not specifically described here.

A change of α is proportional to a coefficient of α. That is, more iterations result in a value of α closer to 1.

The number of parts after partitioning depends on the division coefficient at a current moment. Different time periods have different partitioning coefficients. The partitioning coefficient selected in this embodiment partitions the individuals into two parts, referred to as the first population, and the second population. The fitness of the first population is less than the fitness of the second population. The fitness of the second population is greater than the fitness of the first population.

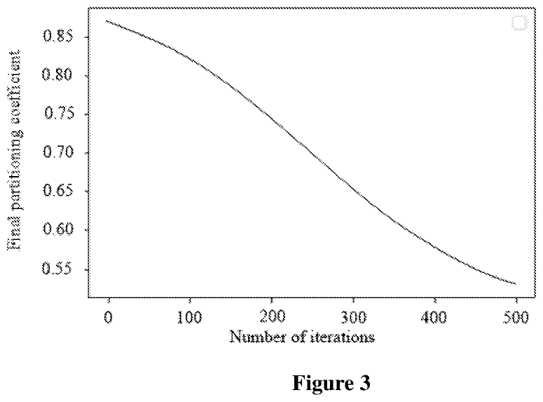

Reference is made to FIG. 3, which is a schematic graph of variations of a with iterations according to an embodiment of the present disclosure. As shown in FIG. 3, α₀=0.5, α_{range}=0.4, T=500 are set, an abscissa in FIG. 3 indicates T, and an ordinate indicates α₀.

The quantity of individuals in the first population pertaining to the Levy flight algorithm satisfies

$$Numlevy = N * α$$

Where Numlevy represents the quantity of individuals in the first population updated by using the Levy flight algorithm, N represents a total quantity of individuals, N is an integer, and a represents a current partitioning coefficient.

The quantity of populations in the second population pertaining to the particle swarm algorithm satisfies

$$Numpso = N - Numlevy$$

where Numpso represents a number of individuals in the first population updated by using the particle swarm algorithm, and N represents a total quantity of individuals.

In step 104, values of the to-be-identified parameters in each individual in the second population are updated by using a particle swarm algorithm, values of the to-be-identified parameters in each individual in the first population are updated by using a Levy flight algorithm.

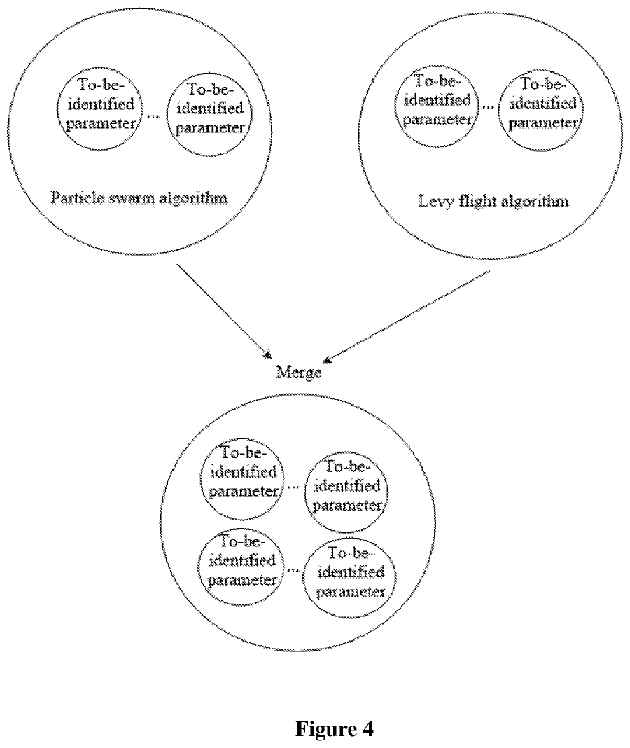

Reference is made to FIG. 4, which shows a schematic diagram of merging of a first population and a second population after to-be-identified parameters in the populations are updated through two algorithms respectively in a method for identifying a parameter of a battery model according to an embodiment of the present disclosure. In step 104, as shown in FIG. 4, the update of parameter values in the first population and the second population through the two different algorithms may be achieved through the following steps.

The first population, with the Levy flight algorithm, satisfies:

$${X}_{i}^{( t + 1 )} = {X}_{i}^{( t )} + {α}_{2} levy ( β ) ; \\ Levy ( β ) \sim \frac{u}{{v}^{\frac{1}{β}}} ;$$

The second population, with the particle swarm algorithm linearly decreasing based on inertia weights, satisfies:

$${w}^{( t )} = ( {w}_{ini} - {w}_{end} ) ( T - t ) / T + {w}_{end} ;$$

where α₂ represents a step factor, X represents to-be-identified parameters in individuals in the first population, Xᵢ^{(t+1)} represents a position of a t-th generation of Xᵢ, w^{(t)} represents a weight of a current iteration, wᵢₙᵢ represents an initial weight, Wend represents a final weight, T represents a maximum number of iterations, and t represents a current iteration.

The population is updated based on the weight of the current iteration. The k-th update of an optimal solution of the i-th parameter in the population satisfies:

$${x}_{i}^{k + 1} = {x}_{i}^{k} + {v}_{i}^{k + 1} ,$$

Where vᵢ^{k+1} satisfies

$${v}_{i}^{k + 1} = {w}^{( t )} * {v}_{i}^{k} + {c}_{1} * rand ( 0 , 1 ) * ( p b e s {t}_{i}^{k} - {x}_{i}^{k} ) + {c}_{2} * r a n d ( 0 , 1 ) * ( g b e s {t}^{k} - {x}_{i}^{k} ) ;$$

Where c₁ represents an individual learning factor for the optimal solution, w^{(t)} represents a weight of a current iteration, c₂ represents a social learning factor for the optimal solution, rand(0, 1) represents a random floating point number between 0 and 1, vᵢ^{k+1} represents a velocity vector of the i-th optimal solution to the power of (k+1), pbestᵢ^{k} represents an optimal historical update value of an i-th optimal solution by the k-th update, gbest^{k} represents an optimal historical update value of all optimal solutions by the k-th update.

In step 105, the first population and the second population are merged after the to-be-identified parameters are updated, to obtain individuals having updated to-be-identified parameters; a second fitness of each of the individuals having updated to-be-identified parameters is calculated; and the second fitness of each individual is compared with the first fitness of the individual, and the individual having a smaller fitness value is retained.

In an implementation, in calculation of the first fitness of an individual, the individual may be regarded as a parent individual. The to-be-identified parameters in the parent individual are updated through the above steps 100 to 105. Here, the individual with updated to-be-identified parameter may be regarded as a child individual (for calculation of the second fitness of the individual). In a case that the second fitness of the child individual is less than the first fitness of the parent individual, the child individual is retained. In a case that the second fitness of the child individual is greater than the first fitness of the parent individual, the parent individual is retained. In this embodiment, a smaller fitness results in a value closer to an actual value. Therefore, the individual having less fitness is preferred.

The second fitness satisfies:

$$M S {E}_{2} = \frac{1}{m} {\sum }_{i = 1}^{m} {( {\hat{V}}_{i} - {\vec{V}}_{i} )}^{2} ;$$

where MSE₂ represents the second fitness of an individual, \hat{V}ᵢ represents a simulated voltage recorded in a correspondence relationship between an i-th simulated voltage and an actual voltage in a correspondence relationship between m simulated voltages and actual voltages, \vec{V}ᵢ represents an actual voltage recorded in correspondence relationship between an i-th simulated voltage and an actual voltage in a correspondence relationship between m simulated voltages and actual voltages, and m represents a quantity of correspondence relationship between a simulated voltage and an actual voltage.

In step 105, the to-be-identified parameters in the individuals after merging are updated, and the fitness of each individual is calculated.

In step 106, a parameter value of an individual having updated to-be-identified parameters which corresponds to a smallest second fitness is determined as a global optimal parameter of the updated to-be-identified parameters, in a case that the smallest second fitness is less than the fitness threshold; and the global optimal parameter of the updated to-be-identified parameters is determined as parameter data of the cell.

The determined parameter data of the cell is the parameter value that needs to be monitored for the energy storage power station.

Based on the above, in the method for identifying a parameter of a battery model provided in the embodiments of the present disclosure, the required to-be-identified parameters are obtained by establishing the electrochemical model of the core. All the to-be-identified parameters are formed into an individual. An optimal parameter of the individual is determined through multiple iterations. Each individual is initialized and a first fitness is calculated. An individual having the smallest first fitness among all individuals is determined as a global optimal parameter. In a case that the first fitness of at least one of the individuals is less than the fitness threshold, the global optimal parameter is determined as parameter data of the cell. In a case that the first fitness of each individual is greater than or equal to the fitness threshold, then the process proceeds to sorting all the individuals in an ascending order based on magnitudes of the first fitness and partition the individuals into two parts, i.e., the first population and the second population. The first fitness of the first population is smaller than that of the second population, or in other words, the first fitness of the second population is relatively great. The to-be-identified parameters in the first population are updated by using the Levy flight algorithm. The to-be-identified parameters in the second population are updated by using the particle swarm algorithm. After the update, the two populations are merged into one and the second fitness is calculated and compared with the first fitness. An individual having a smaller fitness is retained. The process terminates in a case that the second fitness is less than the fitness threshold. Otherwise, the individuals are partitioned again, until the re-calculated second fitness is less than the fitness threshold. Compared with the conventional technology which requires multiple manual measurements of a cell-related parameters, the parameter data that needs to be identified for the cell can be automatically obtained through the method in the present disclosure, without manual acquisition for the multiple parameters in the cell. Hence, a labor intensity and labor cost can be effectively reduced. In addition, with the randomness and global optimization characteristics of the particle swarm algorithm and the fast optimization characteristics of the Levy flight algorithm, an excellence of parameter identification for a cell in a high-dimensional space is further improved, and an accuracy of the parameter identification for the cell is improved.

### Embodiment 2

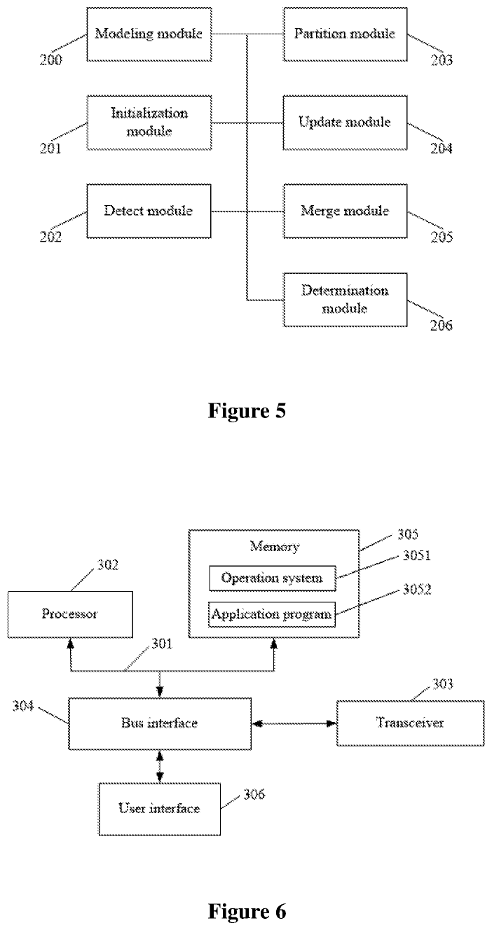

Reference is made to FIG. 5, which shows a schematic diagram of connection of modules in an apparatus for identifying a parameter of a battery model. An apparatus for identifying a parameter of a battery model is further provided according to this embodiment of the present disclosure. The apparatus includes a modeling module 200, an initialization module 201, a detection module 202, a partition module 203, an update module 204, a merge module 205, and a determination module 206.

The modeling module 200 is configured to establish an electrochemical model of a cell in an energy storage power station, obtain required to-be-identified parameters from the electrochemical model to form an individual. The individual is a collection of all the to-be-identified parameters, and a quantity of the individual is more than one.

The initialization module 201 is configured to: perform multiple iterations on values of the to-be identified parameters in the individual; determine an optimal parameter from the individual; initialize all individuals; calculate, for each of the individuals, a first fitness of the individual; and determine a to-be-identified parameter from an individual having a smallest first fitness among all the individuals as a global optimal parameter.

The detect module 202 is configured to determine the global optimal parameter as parameter data of the cell, in a case that any of the individuals has a first fitness less than a fitness threshold.

The partition module 203 is configured to sort the individuals in an ascending order based on magnitudes of the first fitness, and determine a partitioning coefficient and partition the individuals into two parts by using the partitioning coefficient to obtain a first population and a second population, in a case that each of the individuals has a first fitness greater than or equal to the fitness threshold.

The update module 204 is configured to: update, by using a particle swarm algorithm, values of the to-be-identified parameters in each individual in the second population; and update, by using a Levy flight algorithm, values of the to-be-identified parameters in each individual in the first population.

The merge module 205 is configured to: merge the first population and the second population, after the to-be-identified parameters are updated, to obtain individuals having updated to-be-identified parameters; calculate a second fitness of each of the individuals having updated to-be-identified parameters; and compare the second fitness of each individual with the first fitness of the individual, and retain the individual having a smaller fitness value.

The determination module 206 is configured to determine a parameter value of an individual having updated to-be-identified parameters which corresponds to a smallest second fitness as a global optimal parameter of the updated to-be-identified parameters, in a case that the smallest second fitness is less than the fitness threshold; and determine the global optimal parameter of the updated to-be-identified parameters as parameter data of the cell.

In an implementation, the initialization module 201 includes:
inputting values of the to-be-identified parameters of each individual and condition data into the electrochemical model to obtain a simulated voltage of the individual, and determining the first fitness of each individual based on the simulated voltage, where the first fitness satisfies:

$$M S {E}_{1} = \frac{1}{m} {\sum }_{i = 1}^{m} {( {\hat{V}}_{i} - {\vec{V}}_{i} )}^{2} ;$$

where MSE₁ represents the first fitness of an individual, \hat{V}ᵢ represents a simulated voltage recorded in a correspondence relationship between an i-th simulated voltage and an actual voltage in a correspondence relationship between m simulated voltages and actual voltages, \vec{V}ᵢ represents an actual voltage recorded in correspondence relationship between an i-th simulated voltage and an actual voltage in a correspondence relationship between m simulated voltages and actual voltages, and m represents a quantity of correspondence relationship between a simulated voltage and an actual voltage.

In an implementation, the partition module 203 includes that:
the partitioning coefficient satisfies

$$α = {α}_{0} + \frac{{α}_{r a n g e}}{1 + exp ( 0.01 ( t - T / 2 ) )} ;$$

Where α represents a current partitioning coefficient, α₀ represents a final partitioning coefficient, α_{range} represents a revised partitioning coefficient, α+α_{range} represents a start partitioning coefficient, T represents a maximum number of iterations, and t represents a current iteration.

In an implementation, the partition module further includes that:
the first population pertaining to the Levy flight algorithm satisfies

$$Numlevy = N * α , ;$$

where N represents a total quantity of individuals, a represents a current partitioning coefficient, Numlevy represents a quantity of individuals to be updated through the levy flight algorithm, and Numlevy is an integer; and the second population pertaining to the particle swarm algorithm satisfies

$$Numpso = N - Numlevy ;$$

where N represents a total quantity of individuals, and Numpso represents a quantity of individuals to be updated through the particle swarm algorithm.

### Embodiment 3

Reference is made to FIG. 6, which shows a schematic structural diagram of an electronic device for identifying a parameter of a battery model according to an embodiment of the present disclosure. As shown in FIG. 6, an electronic device is further provided according to an embodiment of the present disclosure. The electronic device includes a bus 301, a processor 302, a transceiver 303, a bus interface 304, a memory 305, and a user interface 306.

In an embodiment of the present disclosure, the electronic device further includes a computer program stored in the memory 305 and executable on the processor 302. The computer program, when executed by the processor 302, implements the method for identifying a parameter of a battery model according to any of the embodiments.

The transceiver 303 is configured to receive and transmit data under control of the processor 302.

In the embodiment of the present disclosure, a bus structure (represented by the bus 301) includes any number of interconnected buses and bridges. The bus 301 connects various circuits including one or more processors represented by the processor 302 and a memory represented by the memory 305 together.

The bus 301 represents one or more of any one of several types of bus structures, including a memory bus and a memory controller, a peripheral bus, an accelerated graphic port (AGP), a processor or a local bus using any bus structure among various bus architectures. For illustration rather than limitation, such architectures include: an industry standard architecture (ISA) bus, a micro channel architecture (MCA) bus, an extended ISA (EISA) bus, a video electronics standard association (VESA), and a peripheral component interconnect (PCI) bus.

The processor 302 may be an integrated circuit chip with signal processing capabilities. In implementation, each step of the foregoing method embodiment may be completed by an integrated logic circuit of hardware or instructions in the form of software in the processor. The processor includes: a general-purpose processor, a central processing unit (CPU), a network processor (NP), a digital signal processor (DSP), an application specific integrated circuit (ASIC), a field programmable gate array (FPGA), a complex programmable logic device (CPLD), a programmable logic array (PLA), a microcontroller unit (MCU) or other programmable logic device, a discrete gate, a transistor logic device, a discrete hardware component. The methods, steps, and logical block diagrams disclosed in the embodiments of the present disclosure may be implemented or performed. For example, the processor may be a single-core processor or a multi-core processor, and the processor may be integrated on a single chip or located on various chips.

The processor 302 may be a microprocessor or any conventional processor. The steps of the method disclosed in the embodiments of the present disclosure may be directly performed and completed by a hardware decoding processor, or may be performed and completed by a combination of hardware and software modules in the decoding processor. The software module may be located in a readable storage medium known in the art such as a random-access memory (RAM), a flash memory, a read-only memory (ROM), a programmable read-only memory (PROM), an erasable programmable read-only memory (EPROM), and a register. The readable storage medium is located in the memory. The processor reads the information in the memory and completes the steps of the above method in combination with its hardware.

The bus 301 further connects various other circuits such as a peripheral device, a voltage regulator, or a power management circuit, and the bus interface 304 provides an interface between the bus 301 and the transceiver 303, which are well known in the art. Therefore, the bus 1110 and the bus interface 1140 are not further described in the embodiments of the present disclosure.

The transceiver 303 may include one element or multiple elements, e.g., multiple receivers and transmitters, and provide a unit for communicating with various other devices on a transmission medium. For example, the transceiver 303 receives external data from other devices, and sends the data processed by the processor 302 to other devices. Depending on the nature of the computer system, a user interface 306 may be further provided, including a touch screen, a physical keyboard, a display, a mouse, a speaker, a microphone, a trackball, a joystick, and a stylus.

It should be understood that, in the embodiments of the present disclosure, the memory 305 may further include a memory remotely set with respect to the processor 302. The remotely set memory may be connected to the server through a network. One or more parts of the above-mentioned network may be an ad hoc network, an intranet, an extranet, a virtual private network (VPN), a local area network (LAN), a wireless local area network (WLAN), a wide area network (WAN), a wireless wide area network (WWAN), a metropolitan area network (MAN), the Internet (Internet), a public switched telephone network (PSTN), an plain old telephone service network (POTS), a cellular telephone network, a wireless network, a wireless fidelity (Wi-Fi) network and a combination of two or more of the aforementioned networks. For example, the cellular telephone network and the wireless network each may be a global mobile communications (GSM) system, a code division multiple access (CDMA) system, a global interconnection for microwave access (WiMAX) system, a general packet radio service (GPRS) system, a broadband code division multiple access (WCDMA) system, a long-term evolution (LTE) system, an LTE frequency division duplex (FDD) system, an LTE time division duplex (TDD) system, an advanced long term evolution (LTE-A) system, a universal mobile telecommunications (UMTS) system, an enhanced mobile broadband (eMBB) system, a massive machine type of communication (mMTC) system, a ultra-reliable low latency communications (uRLLC) system and the like.

It should be understood that the memory 305 in the embodiment of the present disclosure may be a volatile memory or a non-volatile memory, or may include both a volatile memory and a non-volatile memory. The non-volatile memory includes: a read-only memory (ROM), a programmable read-only memory (PROM), ab erasable programmable read-only memory (EPROM), an electrically erasable programmable read-only memory (EEPROM) or a flash memory.

The volatile memory includes: a random-access memory (RAM), which serves as an external cache. For illustration rather than limitation, various RAM are available, such as: a static random-access memory (SRAM), a dynamic random-access memory (DRAM), a synchronous dynamic random-access memory (SDRAM), a double data rate synchronous dynamic random-access memory (DDRSDRAM), an enhanced synchronous dynamic random-access memory (ESDRAM), a synchronous link dynamic random-access memory (SLDRAM) and a direct Rambus random access memory (DRRAM). The memory 305 of the electronic device described in the embodiments includes, but is not limited to, the above-mentioned memories and other suitable types of memories.

In the embodiments of the present disclosure, the memory 305 stores the following elements of an operating system 3051 and an application program 3052: executable modules, data structures, or a subset thereof, or an extension set thereof.

Specifically, the operating system 3051 includes various system programs, such as a framework layer, a core library layer, a driver layer and the like, for implementing various basic services and processing hardware-based tasks. The application program 3052 includes various application programs 3052, such as a media player and a browser, for implementing various application services. A program that implements the method of the embodiments of the present disclosure may be included in the application program 3052. The application program 3052 includes: an applet, an object, a component, logic, a data structure, and other computer system executable instructions that perform specific tasks or implement specific abstract data types.

### Embodiment 4

In addition, a computer-readable storage medium on which a computer program is stored is further provided according to an embodiment of the present disclosure. When the computer program is executed by the processor, the method for identifying a parameter of a battery model is implemented, and the same technical effects can be achieved. In order to avoid repetition, details are not repeated here.

The computer-readable storage medium includes permanent and non-permanent, removable and non-removable media, and is a tangible device that retains and stores instructions executed by an instruction execution device. The computer-readable storage medium includes: an electronic storage device, a magnetic storage device, an optical storage device, an electromagnetic storage device, a semiconductor storage device, and any suitable combination of the foregoing. The computer-readable storage medium includes: a phase change memory (PRAM), a static random access memory (SRAM), a dynamic random access memory (DRAM), other types of random access memory (RAM), a read-only memory (ROM), a non-volatile random access memory (NVRAM), an electrically erasable programmable read-only memory (EEPROM), a flash memory or other memories, a compact disc read-only memory (CD-ROM), a digital versatile disc (DVD) or other optical storage device, a magnetic cassette memory, a magnetic tape disk memory or other magnetic storage devices, a memory stick, a mechanical encoding device (such as a punched card or raised structure in a groove on which instructions are recorded) or any other non-transmission medium, and is configured to store information that can be accessed by a computing device. According to the definition in the embodiments of the present disclosure, the computer-readable storage medium does not include temporary signals, such as radio waves or other freely transmitted electromagnetic waves, electromagnetic waves transmitted through waveguides or other transmission media (e.g., a light pulse passing through an optical fiber cable) or electrical signals transmitted through wires.

In the embodiments of the present disclosure, it should be understood that the disclosed apparatus, electronic device, and method may be implemented in other ways. For example, the device embodiments described above are only illustrative. For example, the division of the modules or units is only a logical function division, and there may be other division manners in actual implementation. For example, multiple units or components may be combined or integrated into another system, or some features may be omitted or not implemented. In addition, the shown or discussed mutual coupling or direct coupling or communication connection may be indirect coupling or communication connection through some interfaces, devices or units, and may also be electrical, mechanical or other forms of connection.

The units described as separate components may or may not be physically separate. Components shown as units may or may not be a physical unit, that is, may be located in one position or distributed on multiple network units. Some or all of the units may be selected according to actual needs to solve the problems to be solved by the solutions of the embodiments of the present disclosure.

In addition, the functional units in the various embodiments of the present disclosure may be integrated into one processing unit, or the units may separate physically, or two or more units may be integrated into one unit. The above-mentioned integrated unit may be implemented in the form of hardware or software functional unit.

If the integrated unit is implemented in the form of a software functional unit and sold or used as an independent product, the integrated unit may be stored in a computer-readable storage medium. Based on this understanding, the technical solutions of the embodiments of the present disclosure are essentially or a part that contributes to the conventional technology, or all or part of the technical solutions may be embodied in the form of a computer software product. The computer software product is stored in a storage medium and includes a number of instructions so that a computer device (such as a personal computer, a server, a data center or other network devices) execute all or part of the steps of the method described in the embodiments of the present disclosure. The aforementioned storage medium includes various media capable of storing program codes as listed above.

In the description of the embodiments of the present disclosure, those skilled in the art should understand that the embodiments of the present disclosure may be implemented as a method, an apparatus, an electronic device, and a computer-readable storage medium. Therefore, the embodiments of the present disclosure may be specifically implemented in the following forms: complete hardware, complete software (including firmware, resident software, microcode and the like), and a combination of hardware and software. In addition, in some embodiments, the embodiments of the present disclosure may also be implemented in the form of a computer program product in one or more computer-readable storage media, and the computer-readable storage medium includes computer program codes.

The aforementioned computer-readable storage medium may adopt any combination of one or more computer-readable storage media. The computer-readable storage medium includes: an electrical, magnetic, optical, electromagnetic, infrared, or semiconductor system, device, or device, or any combination of the above. More specific examples of computer-readable storage media include: a portable computer disk, a hard disk, a random-access memory (RAM), a read-only memory (ROM), an erasable programmable read-only memory (EPROM), a flash memory, an optical fiber, a compact disc read-only memory (CD-ROM), an optical storage device, a magnetic storage device or any combination of the above. In the embodiments of the present disclosure, the computer-readable storage medium may be any tangible medium that includes or stores a program, and the program may be executed by an instruction execution system, apparatus, or device, or in combination therewith.

The computer program code included in the above-mentioned computer-readable storage medium may be transmitted by any suitable medium, including: a wireless medium, a wired medium, an optical cable, radio frequency (RF), or any suitable combination of the above.

The computer program codes for implementing the operations in the embodiments of the present disclosure may be written in the form of assembly instructions, instruction set architecture (ISA) instructions, machine instructions, machine-related instructions, microcode, firmware instructions, state setting data, integrated circuit configuration data, or in one or more programming languages or a combination thereof. The programming language includes object-oriented programming languages, such as Java, Smalltalk, and C++, as well as conventional procedural programming languages, such as C language or similar programming languages. The computer program codes may be executed entirely on the user computer, partly on the user computer, executed as an independent software package, partly on the user computer and partly on a remote computer, and completely executed on a remote computer or server. In the case of a remote computer, the remote computer can be connected to a user computer or an external computer through any kind of network, including: a local area network (LAN) or a wide area network (WAN).

The embodiments of the present disclosure describe the provided method, device, and the electronic device through flowcharts and/or block diagrams.

It should be understood that each block in the flowcharts and/or block diagrams and the combination of blocks in the flowcharts and/or block diagrams may be implemented by computer readable program instructions. These computer-readable program instructions may be provided to the processor of a general-purpose computer, a special-purpose computer, or other programmable data processing device, to produce a machine. These computer-readable program instructions are executed by a computer or other programmable data processing device to generate a device that implements the functions/operations specified by the blocks in the flowcharts and/or block diagrams.

These computer-readable program instructions may also be stored in a computer-readable storage medium that can operate a computer or other programmable data processing device in a specific manner. In this way, the instructions stored in the computer-readable storage medium produce an instruction device product that includes the functions/operations specified in the blocks in the flowcharts and/or block diagrams.

Alternatively, the computer-readable program instructions are loaded onto a computer, other programmable data processing device, or other device, so that a series of operation steps are executed on the computer, other programmable data processing device, or other device to produce a computer-implemented process, so that the instructions executed on the computer or other programmable data processing device can provide a process for implementing the functions/operations specified by the blocks in the flowcharts and/or block diagrams.

Specific implementations of the embodiments of the present disclosure are described above, and the scope of protection of the embodiments of the present disclosure is not limited thereto. Any person skilled in the art can easily conceive of changes or substitutions within the technical scope disclosed in the embodiments of the present disclosure, and these changes or substitutions should be covered by the scope of protection of the embodiments of the present disclosure. Therefore, the scope of protection of the embodiments of the present disclosure should be subject to the protection scope of the claims.

1. A method for identifying a parameter of a battery model, applied to an energy storage power station, wherein the method comprises:
establishing an electrochemical model of a cell in the energy storage power station, and for each of a plurality of individuals, obtaining a plurality of to-be-identified parameters from the electrochemical model to form the individual, wherein the individual is a collection of the plurality of to-be-identified parameters;
performing, for each of the plurality of individuals, a plurality of iterations on values of the plurality of to-be identified parameters in the individual, determining, for each of the plurality of individuals, an optimal parameter from the individual, initializing the plurality of individuals, and calculating, for each of the plurality of individuals, a first fitness of the individual;
determining a to-be-identified parameter from an individual having a smallest first fitness among the plurality of individuals as a global optimal parameter;
determining the global optimal parameter as parameter data of the cell, in a case that any of the plurality of individuals has a first fitness less than a fitness threshold;
sorting the plurality of individuals in an ascending order based on magnitudes of the first fitness, and determining a partitioning coefficient and partitioning the plurality of individuals into two parts by using the partitioning coefficient to obtain a first population and a second population, in a case that each of the plurality of individuals has a first fitness greater than or equal to the fitness threshold;
updating, by using a particle swarm algorithm, values of the plurality of to-be-identified parameters in each individual in the second population, and updating, by using a Levy flight algorithm, values of the plurality of to-be-identified parameters in each individual in the first population;
merging the first population and the second population, after the to-be-identified parameters are updated, to obtain a plurality of individuals having updated to-be-identified parameters, and calculating a second fitness of each of the plurality of individuals having updated to-be-identified parameters, comparing, for each of the plurality of individuals, the second fitness of the individual with the first fitness of the individual, and retaining an individual among the plurality of individuals having a smaller fitness value;
determining a parameter value of an individual among the plurality of individuals having the updated to-be-identified parameters which corresponds to a smallest second fitness as a global optimal parameter of the updated to-be-identified parameters, in a case that the smallest second fitness is less than the fitness threshold, and determining the global optimal parameter of the updated to-be-identified parameters as parameter data of the cell; and
monitoring the parameter data in the energy storage power station.

2. The method according to claim 1, wherein the initializing the plurality of individuals, and calculating, for each of the plurality of individuals, a first fitness of the individual comprises: for each of the plurality of individuals,
inputting values of the to-be-identified parameters of the individual and condition data into the electrochemical model to obtain a simulated voltage of the individual, and determining the first fitness of the individual based on the simulated voltage, wherein the first fitness satisfies:
$$M S {E}_{1} = \frac{1}{m} {\sum }_{i = 1}^{m} {( {\hat{V}}_{i} - {\vec{V}}_{i} )}^{2} ;$$
where MSE₁ represents the first fitness of an individual, \hat{V}ᵢ represents a simulated voltage recorded in a correspondence relationship between an i-th simulated voltage and an actual voltage in a correspondence relationship between m simulated voltages and actual voltages, \vec{V}ᵢ represents an actual voltage recorded in correspondence relationship between an i-th simulated voltage and an actual voltage in a correspondence relationship between m simulated voltages and actual voltages, and m represents a quantity of correspondence relationship between a simulated voltage and an actual voltage.

3. The method according to claim 1, wherein the sorting the plurality of individuals in an ascending order based on magnitudes of the first fitness, and determining a partitioning coefficient and partitioning the plurality of individuals into two parts by using the partitioning coefficient, in a case that each of the plurality of individuals has a first fitness greater than or equal to the fitness threshold comprises that:
the partitioning coefficient satisfies:
$$α = {α}_{0} + \frac{{α}_{range}}{1 + exp ( 0.01 ( t - T / 2 ) )} ;$$
where α represents a current partitioning coefficient, α₀ represents a final partitioning coefficient, α₀+α_{range} represents a start partitioning coefficient, T represents a maximum number of iterations, and t represents a current iteration.

4. The method according to claim 1, wherein the sorting the plurality of individuals in an ascending order based on magnitudes of the first fitness, and determining a partitioning coefficient and partitioning the plurality of individuals into two parts by using the partitioning coefficient, in a case that each of the plurality of individuals has a first fitness greater than or equal to the fitness threshold further comprises that:
the first population pertaining to the Levy flight algorithm satisfies
$$Numlevy = N * α ;$$
where N represents a total quantity of individuals, a represents a current partitioning coefficient, Numlevy represents a quantity of individuals to be updated through the levy flight algorithm, and Numlevy is an integer; and
the second population pertaining to the particle swarm algorithm satisfies
$$Numpso = N - Numlevy ;$$
where N represents a total quantity of individuals, Numpso represents a quantity of individuals to be updated through the particle swarm algorithm.

5. (canceled)

6. (canceled)

7. (canceled)

8. (canceled)

9. An electronic device, comprising:
a bus;
a transceiver;
a memory;
a processor; and
a computer program stored on the memory and executable on the processor, wherein
the transceiver, the memory, and the processor are connected to each other via the bus, and the computer program, when executed by the processor, performs a method for identifying a parameter of a battery model, applied to an energy storage power station, wherein the method comprises:
establishing an electrochemical model of a cell in the energy storage power station, and for each of a plurality of individuals, obtaining a plurality of to-be-identified parameters from the electrochemical model to form the individual, wherein the individual is a collection of the plurality of to-be-identified parameters;
performing, for each of the plurality of individuals, a plurality of iterations on values of the plurality of to-be identified parameters in the individual, determining, for each of the plurality of individuals, an optimal parameter from the individual, initializing the plurality of individuals, and calculating, for each of the plurality of individuals, a first fitness of the individual;
determining a to-be-identified parameter from an individual having a smallest first fitness among the plurality of individuals as a global optimal parameter;
determining the global optimal parameter as parameter data of the cell, in a case that any of the plurality of individuals has a first fitness less than a fitness threshold;
sorting the plurality of individuals in an ascending order based on magnitudes of the first fitness, and determining a partitioning coefficient and partitioning the plurality of individuals into two parts by using the partitioning coefficient to obtain a first population and a second population, in a case that each of the plurality of individuals has a first fitness greater than or equal to the fitness threshold;
updating, by using a particle swarm algorithm, values of the plurality of to-be-identified parameters in each individual in the second population, and updating, by using a Levy flight algorithm, values of the plurality of to-be-identified parameters in each individual in the first population;
merging the first population and the second population, after the to-be-identified parameters are updated, to obtain a plurality of individuals having updated to-be-identified parameters, and calculating a second fitness of each of the plurality of individuals having updated to-be-identified parameters, comparing, for each of the plurality of individuals, the second fitness of the individual with the first fitness of the individual, and retaining an individual among the plurality of individuals having a smaller fitness value;
determining a parameter value of an individual among the plurality of individuals having the updated to-be-identified parameters which corresponds to a smallest second fitness as a global optimal parameter of the updated to-be-identified parameters, in a case that the smallest second fitness is less than the fitness threshold, and determining the global optimal parameter of the updated to-be-identified parameters as parameter data of the cell; and
monitoring the parameter data in the energy storage power station.

10. A computer-readable storage medium storing a computer program, wherein
the computer program, when executed by a processor, performs a method for identifying a parameter of a battery model, applied to an energy storage power station, wherein the method comprises:
establishing an electrochemical model of a cell in the energy storage power station, and for each of a plurality of individuals, obtaining a plurality of to-be-identified parameters from the electrochemical model to form the individual, wherein the individual is a collection of the plurality of to-be-identified parameters;
performing, for each of the plurality of individuals, a plurality of iterations on values of the plurality of to-be identified parameters in the individual, determining, for each of the plurality of individuals, an optimal parameter from the individual, initializing the plurality of individuals, and calculating, for each of the plurality of individuals, a first fitness of the individual;
determining a to-be-identified parameter from an individual having a smallest first fitness among the plurality of individuals as a global optimal parameter;
determining the global optimal parameter as parameter data of the cell, in a case that any of the plurality of individuals has a first fitness less than a fitness threshold;
sorting the plurality of individuals in an ascending order based on magnitudes of the first fitness, and determining a partitioning coefficient and partitioning the plurality of individuals into two parts by using the partitioning coefficient to obtain a first population and a second population, in a case that each of the plurality of individuals has a first fitness greater than or equal to the fitness threshold;
updating, by using a particle swarm algorithm, values of the plurality of to-be-identified parameters in each individual in the second population, and updating, by using a Levy flight algorithm, values of the plurality of to-be-identified parameters in each individual in the first population;
merging the first population and the second population, after the to-be-identified parameters are updated, to obtain a plurality of individuals having updated to-be-identified parameters, and calculating a second fitness of each of the plurality of individuals having updated to-be-identified parameters, comparing, for each of the plurality of individuals, the second fitness of the individual with the first fitness of the individual, and retaining an individual among the plurality of individuals having a smaller fitness value;
determining a parameter value of an individual among the plurality of individuals having the updated to-be-identified parameters which corresponds to a smallest second fitness as a global optimal parameter of the updated to-be-identified parameters, in a case that the smallest second fitness is less than the fitness threshold, and determining the global optimal parameter of the updated to-be-identified parameters as parameter data of the cell; and
monitoring the parameter data in the energy storage power station.

11. The electronic device according to claim 9, wherein the initializing the plurality of individuals, and calculating, for each of the plurality of individuals, a first fitness of the individual comprises: for each of the plurality of individuals,
inputting values of the to-be-identified parameters of the individual and condition data into the electrochemical model to obtain a simulated voltage of the individual, and determining the first fitness of the individual based on the simulated voltage, wherein the first fitness satisfies:
$$M S {E}_{1} = \frac{1}{m} {\sum }_{i = 1}^{m} {( {\hat{V}}_{i} - {\vec{V}}_{i} )}^{2} ;$$
where MSE₁ represents the first fitness of an individual, \hat{V}ᵢ represents a simulated voltage recorded in a correspondence relationship between an i-th simulated voltage and an actual voltage in a correspondence relationship between m simulated voltages and actual voltages, \vec{V}ᵢ represents an actual voltage recorded in correspondence relationship between an i-th simulated voltage and an actual voltage in a correspondence relationship between m simulated voltages and actual voltages, and m represents a quantity of correspondence relationship between a simulated voltage and an actual voltage.

12. The electronic device according to claim 9, wherein the sorting the plurality of individuals in an ascending order based on magnitudes of the first fitness, and determining a partitioning coefficient and partitioning the plurality of individuals into two parts by using the partitioning coefficient, in a case that each of the plurality of individuals has a first fitness greater than or equal to the fitness threshold comprises that:
the partitioning coefficient satisfies:
$$α = {α}_{0} + \frac{{α}_{range}}{1 + exp ( 0.01 ( t - T / 2 ) )}$$
where α represents a current partitioning coefficient, α₀ represents a final partitioning coefficient, α₀+α_{range} represents a start partitioning coefficient, T represents a maximum number of iterations, and t represents a current iteration.

13. The electronic device according to claim 9, wherein the sorting the plurality of individuals in an ascending order based on magnitudes of the first fitness, and determining a partitioning coefficient and partitioning the plurality of individuals into two parts by using the partitioning coefficient, in a case that each of the plurality of individuals has a first fitness greater than or equal to the fitness threshold further comprises that:
the first population pertaining to the Levy flight algorithm satisfies
$$Numlevy = N * α ;$$
where N represents a total quantity of individuals, α represents a current partitioning coefficient, Numlevy represents a quantity of individuals to be updated through the levy flight algorithm, and Numlevy is an integer; and
the second population pertaining to the particle swarm algorithm satisfies
$$Numpso = N - Numlevy ;$$
where N represents a total quantity of individuals, Numpso represents a quantity of individuals to be updated through the particle swarm algorithm.
